(19) United States
(12) Patent Application Publication
(10) Pub. No.: US 2021/0199386 A1
(43) Pub. Date: Jul. 1, 2021

(54) VAPOR CHAMBER STRUCTURE

(71) Applicant: ASIA VITAL COMPONENTS (CHINA) CO., LTD., Shenzhen (CN)

(72) Inventors: Jian Zhang, Shenzhen (CN); Xiwen Xiong, Shenzhen (CN); Guangdong Chen, Shenzhen (CN)

(21) Appl. No.: 16/853,773

(22) Filed: Apr. 21, 2020

(30) Foreign Application Priority Data
Dec. 30, 2019 (TW) 108148419

(51) Int. Cl. F28D 15/04; F28D 15/02

(52) U.S. Cl. CPC F28D 15/046; F28D 15/0275; F28D 15/0233

(57) ABSTRACT

A vapor chamber structure includes: a first plate body and a second plate body, which are mechanically processed and thinned, the first plate body having a first side, a second side and an opening, the second plate body having a third side and a fourth side, the first and second plate bodies being correspondingly mated with each other to define an airtight chamber, a working liquid being filled in the airtight chamber; a heat conduction block disposed at the opening, the heat conduction block having a first face and a second face; a first capillary structure layer disposed on the first side of the first plate body; and a second capillary structure layer formed on the second face of the heat conduction block. In case the first and second plate bodies are thinned to cause insufficient structural strength and planarity, the heat conduction block can reinforce the vapor chamber structure.

This application claims the priority benefit of Taiwan patent application number 108148419 filed on Dec. 30, 2019.

### BACKGROUND OF THE INVENTION

### 1. Field of the Invention

The present invention relates generally to a vapor chamber structure, and more particularly to a vapor chamber structure, which can increase the structural strength of the vapor chamber structure after thinned.

### 2. Description of the Related Art

A vapor chamber is an often seen heat transfer component with quick heat conduction effect. The vapor chamber is widely applied to various heat dissipation fields.

Currently, there is a trend to thin or miniaturize various electronic equipments or devices. With this trend, the internal space of the electronic device for arranging the electronic components is narrowed. As a result, the internal space of the electronic device for arranging the heat dissipation and heat conduction components also become quite limited. Therefore, the heat dissipation and heat conduction components must be also thinned or miniaturized with the internal space. Thinned vapor chambers have been developed long since in this field. In order to achieve the thinned vapor chamber, the volume and thickness of all components of the entire vapor chamber inevitably must be thinned and minified, including the thickness of the upper and lower plate bodies and the internal capillary structure. After the upper and lower plate bodies are mated with each other and the periphery is sealed, the height of the internal chamber of the vapor chamber is also narrowed (reduced). After the upper and lower plate bodies are thinned, the mechanical strength of the plate bodies themselves is affected so that the upper and lower plate bodies are very apt to deform or even fracture due to very minor compression or collision.

In addition, after the plate bodies or tube bodies are mechanically processed and thinned, the material is tensioned and stretched so that the entire structure becomes thinner. As a result, the extent to which the plate bodies can be further shaped is limited. Also, the support and structural strength are also reduced so that the plate bodies cannot be over-shaped or bent. Otherwise, the plate bodies are apt to break or fracture to cause poor tightness and defective product. Moreover, this will lead to insufficient contact strength. In the case that the plate bodies or tube bodies need to be additionally formed with raised platform structure protruding from the plate bodies or tube bodies, because the thickness of the plate material of the thinned plate bodies or tube bodies becomes thinner, there is no excessive thickness for further mechanical processing to form the raised platform structure.

According to the above, the thinned vapor chamber has the following shortcomings:
1. The entire plate material has thinner thickness and becomes lightweight. However, the strength is weakened.
2. It is hard to stretch or punch the plate bodies to form the raised platform.
3. After formed, the strength and planarity of the raised platform are very poor.
4. The section of the raised platform has thinner thickness so that it is impossible to further mechanically process the raised platform to cut/mill and manufacture the capillary structure (channels).
5. The thickness of the substrate plate bodies becomes thinner so that the chamber becomes larger. However, the structural strength of the entire structure is weakened.

It is therefore tried by the applicant to provide a vapor chamber structure to solve the above problems existing in the conventional vapor chamber structure. The vapor chamber structure of the present invention can improve the shortcoming of the conventional vapor chamber structure and keep having good mechanical strength after thinned.

### SUMMARY OF THE INVENTION

It is therefore a primary object of the present invention to provide a vapor chamber structure, which keeps having good mechanical strength after thinned.

To achieve the above and other objects, the vapor chamber structure of the present invention includes a first plate body and a second plate body, which are mechanically processed and thinned, a heat conduction block, a first capillary structure layer and a second capillary structure layer.

The first plate body has a first side, a second side and an opening. The second plate body has a third side and a fourth side. The first and second plate bodies are correspondingly mated with each other to define an airtight chamber. A working liquid is filled in the airtight chamber. The heat conduction block is correspondingly disposed at the opening. The heat conduction block has a first face and a second face. The first capillary structure layer is disposed on the first side of the first plate body. The second capillary structure layer is formed on the second face of the heat conduction block. After the first and second plate bodies are thinned and then further tensioned and stretched or punched, by means of the heat conduction block, the vapor chamber structure can keep having the structural strength without losing the structural strength after the first plate body is further stretched and thinned.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the vapor chamber structure of the present invention;

FIG. 2 is a sectional assembled view of the first embodiment of the vapor chamber structure of the present invention;

FIG. 3 is a sectional assembled view of a second embodiment of the vapor chamber structure of the present invention;

FIG. 4 is a sectional assembled view of a third embodiment of the vapor chamber structure of the present invention;

FIG. 5 is a sectional exploded view of a fourth embodiment of the vapor chamber structure of the present invention; and

FIG. 6 is a sectional assembled view of a fifth embodiment of the vapor chamber structure of the present invention.

### DETAILED DESCRIPTION OF THE PREFERRED EMBODIMENTS

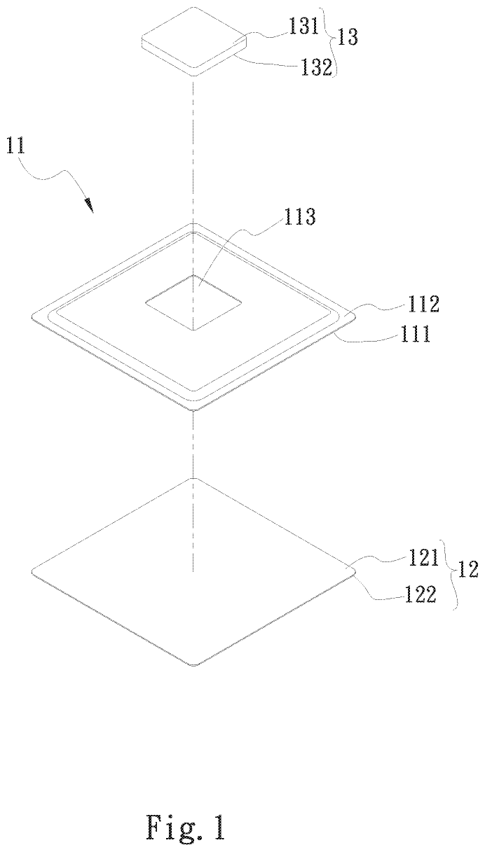

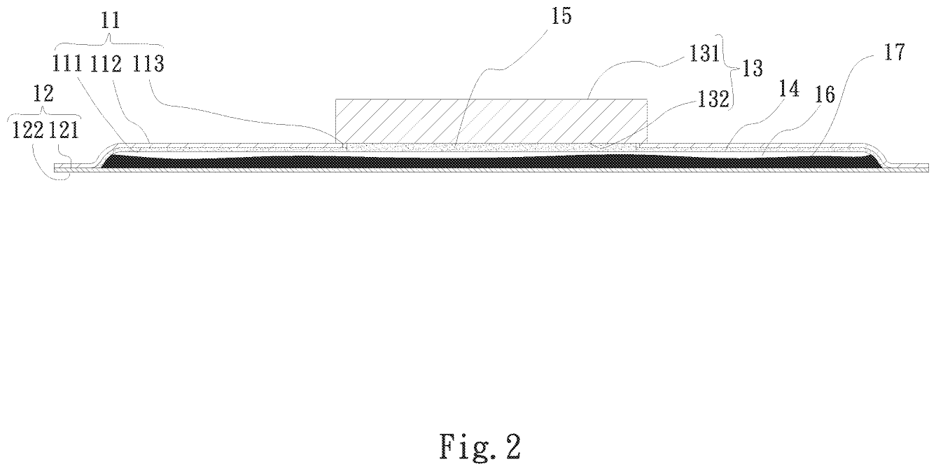

Please refer to FIGS. 1 and 2. FIG. 1 is a perspective exploded view of a first embodiment of the vapor chamber structure of the present invention. FIG. 2 is a sectional assembled view of the first embodiment of the vapor chamber structure of the present invention. As shown in the drawings, the vapor chamber structure of the present invention includes a first plate body 11 and a second plate body 12, which are mechanically processed and thinned, a heat conduction block 13, a first capillary structure layer 14 and a second capillary structure layer 15.

The first plate body 11 has a first side 111, a second side 112 and an opening 113. The first and second sides 111, 112 are respectively positioned on upper and lower sides of the first plate body 11. The opening 113 respectively communicates with the first and second sides 111, 112.

The heat conduction block 13 is correspondingly disposed at the opening 113. The heat conduction block 13 has a first face 131 and a second face 132. The heat conduction block 13 is connected with the first plate body 11 by means of welding, press fit, adhesion, screwing or engagement. The heat conduction block 13 has an area larger than that of the opening 113. The heat conduction block 13 is attached to the surface of the second side 112 of the first plate body 11, (that is, the surface of the second side 112 in adjacency to a periphery of the opening 113) corresponding to the opening 113. The first capillary structure layer 14 is disposed on the first side 111 of the first plate body 11. The second capillary structure layer 15 is disposed on the second face 132 of the heat conduction block 13. The first capillary structure layer 14 and the second capillary structure layer 15 can be connected with each other or disconnected from each other.

The first capillary structure layer 14 is disposed on the first side 111 of the first plate body 11. The second capillary structure layer 15 is formed on the second face 132 of the heat conduction block 13.

The first capillary structure layer 14 and the second capillary structure layer 15 are selected from a group consisting of sintered powder, mesh body, channeled body and fiber body.

The heat conduction block 13 and the first and second plate bodies 11, 12 are made of a material selected from a group consisting of gold, silver, iron, copper, aluminum, stainless steel, copper alloy, aluminum alloy, titanium, titanium alloy, commercial pure titanium and ceramic material. The first and second plate bodies 11, 12 and the heat conduction block 13 can be made of the same material or different materials.

The second plate body 12 has a third side 121 and a fourth side 122. The first and second plate bodies 11, 12 are correspondingly mated with each other to define an airtight chamber 16. A working liquid 17 is filled in the airtight chamber 16 to form the vapor chamber structure of the present invention.

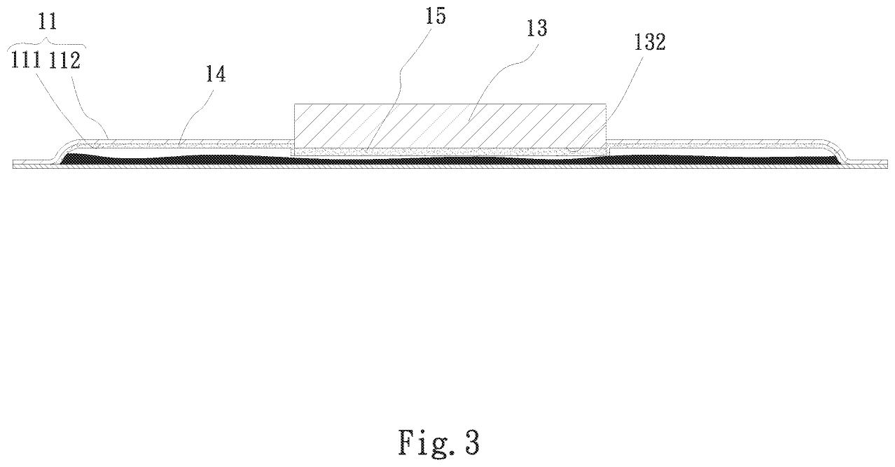

Please refer to FIG. 3, which is a sectional assembled view of a second embodiment of the vapor chamber structure of the present invention. The second embodiment of the vapor chamber structure of the present invention is partially identical to the first embodiment in structure and thus will not be redundantly described hereinafter. The second embodiment is different from the first embodiment in that the heat conduction block 13 has an area smaller than or equal to that of the opening 113. In this embodiment, the heat conduction block 13 is selectively inlaid (by means of engagement or press fit) in the opening 113 (with reference to FIGS. 1 and 2). The first capillary structure layer 14 is disposed on the first side 111 of the first plate body 11. The second capillary structure layer 15 is disposed on the second face 132 of the heat conduction block 13. The first capillary structure layer 14 and the second capillary structure layer 15 are connected with each other or disconnected from each other.

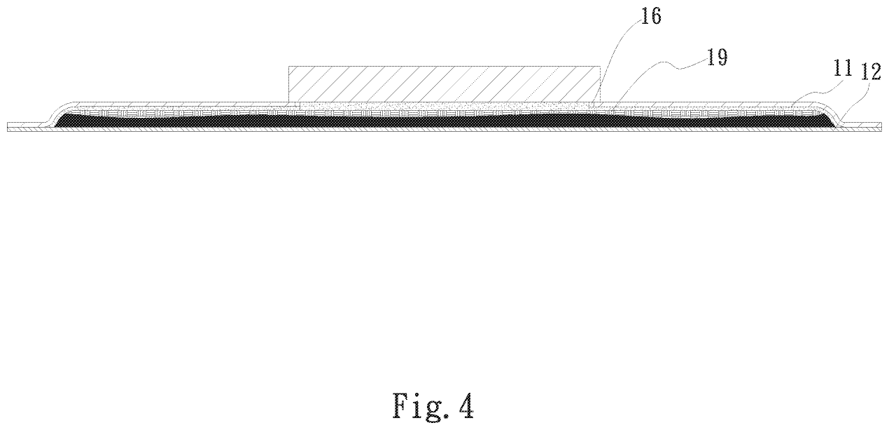

Please refer to FIG. 4, which is a sectional assembled view of a third embodiment of the vapor chamber structure of the present invention. The third embodiment of the vapor chamber structure of the present invention is partially identical to the first embodiment in structure and thus will not be redundantly described hereinafter. The third embodiment is different from the first embodiment in that the vapor chamber structure further has a third capillary structure layer 19. The third capillary structure layer 19 is disposed in the airtight chamber 16 and stacked with the first and second plate bodies 11, 12. The third capillary structure layer 19 is selected from a group consisting of sintered powder, mesh body and fiber body.

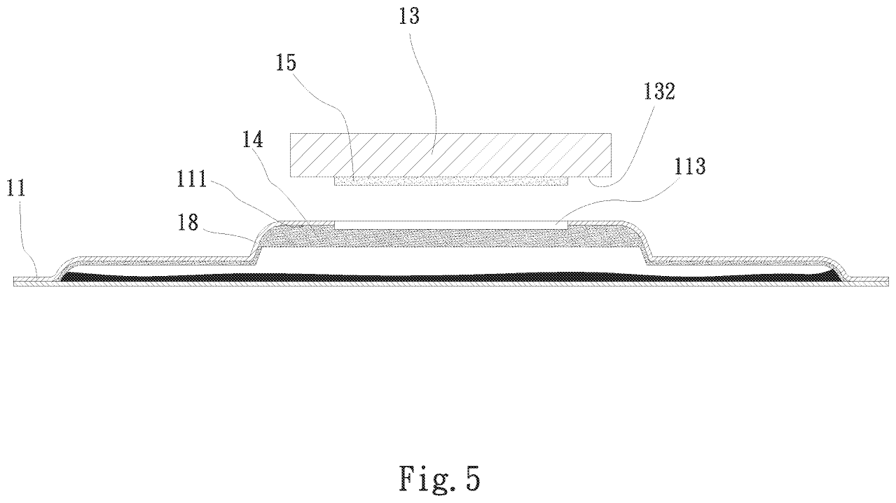

Please refer to FIG. 5, which is a sectional exploded view of a fourth embodiment of the vapor chamber structure of the present invention. The fourth embodiment of the vapor chamber structure of the present invention is partially identical to the first embodiment in structure and thus will not be redundantly described hereinafter. The fourth embodiment is different from the first embodiment in that the first plate body 11 has a raised section 18 protruding from the first side 111 to the second side 112. The opening 113 is correspondingly disposed on the raised section 18. A dent is formed on the first side 111 corresponding to the raised section 18. The heat conduction block 13 is flush with the dent or lower than the dent. The heat conduction block 13 is attached to the surface of the raised section 18 corresponding to the opening 113. The first capillary structure layer 14 is disposed on the first side 111 of the first plate body 11. The second capillary structure layer 15 is disposed on the second face 132 of the heat conduction block 13. The first and second capillary structures 14, 15 are connected with each other.

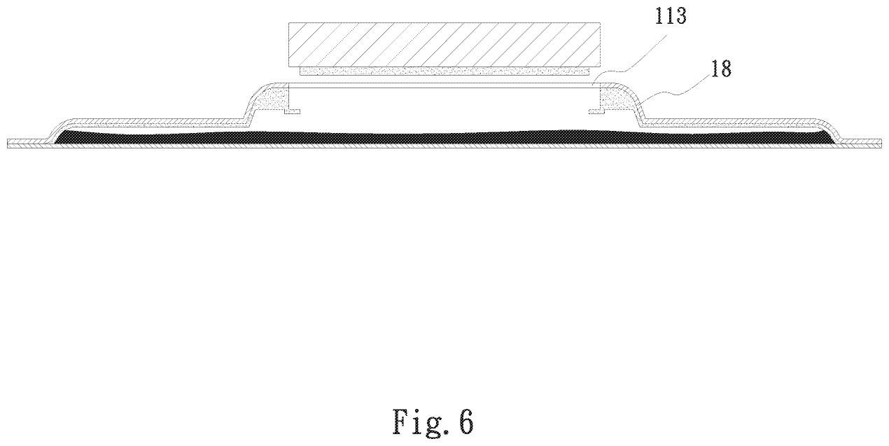

Please refer to FIG. 6, which is a sectional assembled view of a fifth embodiment of the vapor chamber structure of the present invention. The fifth embodiment of the vapor chamber structure of the present invention is partially identical to the fourth embodiment in structure and thus will not be redundantly described hereinafter. The fifth embodiment is different from the fourth embodiment in that the heat conduction block 13 is inlaid in the opening 113 on the raised section 18.

In the precondition that the vapor chamber is thinned or relatively lightweight and thin plate bodies are selectively used as the substrate plate bodies of the vapor chamber, when the plate bodies are mechanically processed and stretched or drawn or rolled to shape the plate bodies, the plate bodies will encounter the limitation of shaping and deformation. For example, when a plate body with extremely thin thickness is selectively used and stretched to form a raised platform in contact with a heat source, the section formed with the raised platform structure will have thickness even thinner than other sections. As a result, the mechanical strength of the raised platform structure will be lower than the other sections.

The primary object of the present invention is to eliminate the above shortcoming. Please further refer to FIGS. 1 to 6. The first plate body 11 is formed with an opening 113 passing through the first plate body 11. The heat conduction block 13 is attached to or inlaid in the opening 113 to reinforce the mechanical strength where the first plate body 11 is disposed. The second capillary structure 15 is disposed on the second face 132 of the heat conduction block 13, which faces the airtight chamber 16. The second capillary structure 15 is directly connected with the first capillary structure 14 disposed on the first plate body 11. Accordingly, the heat transfer effect and vapor-liquid circulation effect are enhanced. Moreover, in the condition that the unit volume is unchanged, the first and second plate bodies 11, 12 are mechanically processed and thinned so that the space of the internal airtight chamber is enlarged to enhance the vapor-liquid circulation efficiency. The heat conduction block 13 increases the structural strength of the thinned first plate body 11. In addition, in the case that the first and second plate bodies 11, 12 are thinned to lead to insufficient structural strength and planarity of the entire structure, the heat conduction block 13 can reinforce the vapor chamber structure.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A vapor chamber structure comprising:
a first plate body and a second plate body, which are mechanically processed and thinned, the first plate body having a first side, a second side and an opening, the second plate body having a third side and a fourth side, the first and second plate bodies being correspondingly mated with each other to define an airtight chamber, a working liquid being filled in the airtight chamber;
a heat conduction block correspondingly disposed at the opening, the heat conduction block having a first face and a second face;
a first capillary structure layer disposed on the first side of the first plate body; and
a second capillary structure layer formed on the second face of the heat conduction block, the first capillary structure layer and the second capillary structure layer being connected with each other or disconnected from each other.

2. The vapor chamber structure as claimed in claim 1, wherein the first plate body has a raised section protruding from the first side to the second side, the opening being correspondingly disposed on the raised section, a dent being formed on the first side corresponding to the raised section, the heat conduction block being flush with the dent or lower than the dent.

3. The vapor chamber structure as claimed in claim 1, wherein the first capillary structure layer and the second capillary structure layer are selected from a group consisting of sintered powder, mesh body, channeled body and fiber body.

4. The vapor chamber structure as claimed in claim 1, wherein the heat conduction block and the first and second plate bodies are made of a material selected from a group consisting of gold, silver, iron, copper, aluminum, stainless steel, copper alloy, aluminum alloy, titanium, titanium alloy, commercial pure titanium and ceramic material.

5. The vapor chamber structure as claimed in claim 1, further comprising a third capillary structure layer, the third capillary structure layer being disposed in the airtight chamber and stacked with the first and second plate bodies.

6. The vapor chamber structure as claimed in claim 5, wherein the third capillary structure layer is selected from a group consisting of sintered powder, mesh body and fiber body.

7. The vapor chamber structure as claimed in claim 1, wherein the heat conduction block is connected with the first plate body by means of welding, press fit or adhesion.

8. The vapor chamber structure as claimed in claim 2, wherein the heat conduction block is attached to a surface of the raised section corresponding to the opening.

9. The vapor chamber structure as claimed in claim 2, wherein the heat conduction block is inlaid in the opening on the raised section.

10. The vapor chamber structure as claimed in claim 1, wherein the heat conduction block is inlaid in the opening.
